(19) United States
(12) Patent Application Publication
(10) Pub. No.: US 2025/0293021 A1
(43) Pub. Date: Sep. 18, 2025

(54) FILM FORMING METHOD AND FILM FORMING APPARATUS

(71) Applicant: Tokyo Electron Limited, Tokyo (JP)

(72) Inventors: Tomohiro NAKAGAWA, Hwaseong-si (KR); Shuji AZUMO, Nirasaki City (JP)

(21) Appl. No.: 19/223,401

(22) Filed: May 30, 2025

Related U.S. Application Data
(63) Continuation of application No. PCT/JP2023/041768, filed on Nov. 21, 2023.

(30) Foreign Application Priority Data
Dec. 6, 2022 (JP) 2022-195000

(51) Int. Cl. H01L 21/02; C23C 16/04; C23C 16/52; C23C 16/56; H01J 37/32

(52) U.S. Cl. CPC H01L 21/02304; C23C 16/042; C23C 16/52; C23C 16/56; H01J 37/32449; H01L 21/02164; H01L 21/0234; H01J 2237/332

(57) ABSTRACT

A film forming method includes: preparing a substrate including a surface of a first insulating film and a surface of a conductive film in different regions of a substrate surface; selectively forming an inhibition film, which inhibits adsorption of a metal catalyst-containing gas, on the surface of the conductive film relative to the surface of the first insulating film; supplying the metal catalyst-containing gas to the substrate surface on which the inhibition film has been formed to selectively adsorb the metal catalyst-containing gas onto the surface of the first insulating film relative to the surface of the conductive film; and supplying a silanol-containing gas to the substrate surface onto which the metal catalyst-containing gas has been adsorbed to form a second insulating film containing silicon and oxygen from the silanol-containing gas, wherein the supplying the metal catalyst-containing gas and the supplying the silanol-containing gas are performed inside different processing containers.

### CROSS-REFERENCE TO RELATED APPLICATION

This application is a bypass continuation application of International Patent Application No. PCT./JP2023/041768 having an international filing date of Nov. 21, 2023 and designating the United States, the international application being based upon and claiming the benefit of priority from Japanese Patent Application No. 2022-195000, filed on Dec. 6, 2022, the entire contents of which are incorporated herein by reference.

### TECHNICAL FIELD

The present disclosure relates to a film forming method and a film forming apparatus.

### BACKGROUND

Patent Document 1 discloses sequentially supplying an inhibition component for suppressing adsorption of a catalytic component onto a substrate, the catalytic component, and a film forming component to the substrate. An example of the inhibition component is a self-assembled monolayer (SAM). An example of the catalytic component is trimethylaluminum (TMA). An example of the film forming component is tris(tert-pentoxy)silanol (TPSOL).

### PRIOR ART DOCUMENTS

### Patent Documents

Patent Document 1: Japanese Patent Laid-Open Publication No. 2022-075394

### SUMMARY

According to one embodiment of the present disclosure, a film forming method includes: preparing a substrate including a surface of a first insulating film and a surface of a conductive film in different regions of a substrate surface; selectively forming an inhibition film, which inhibits adsorption of a metal catalyst-containing gas, on the surface of the conductive film relative to the surface of the first insulating film; supplying the metal catalyst-containing gas to the substrate surface on which the inhibition film has been formed to selectively adsorb the metal catalyst-containing gas onto the surface of the first insulating film relative to the surface of the conductive film; and supplying a silanol-containing gas to the substrate surface onto which the metal catalyst-containing gas has been adsorbed to form a second insulating film containing silicon and oxygen from the silanol-containing gas, wherein the supplying the metal catalyst-containing gas to the substrate surface and the supplying the silanol-containing gas to the substrate surface are performed inside different processing containers.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart illustrating a film forming method according to an embodiment.

FIG. 2A is a cross-sectional view illustrating an example of S101.

FIG. 2B is a cross-sectional view illustrating an example of S102.

FIG. 2C is a cross-sectional view illustrating an example of S103.

FIG. 2D is a cross-sectional view illustrating an example of S104.

FIG. 2E is a cross-sectional view illustrating an example of S105.

FIG. 3A is a cross-sectional view illustrating a first modified example of S101.

FIG. 3B is a cross-sectional view illustrating a second modified example of S101.

FIG. 4 is a plan view illustrating a film forming apparatus according to an embodiment.

FIG. 5 is a cross-sectional view illustrating an example of a first processor in FIG. 4.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

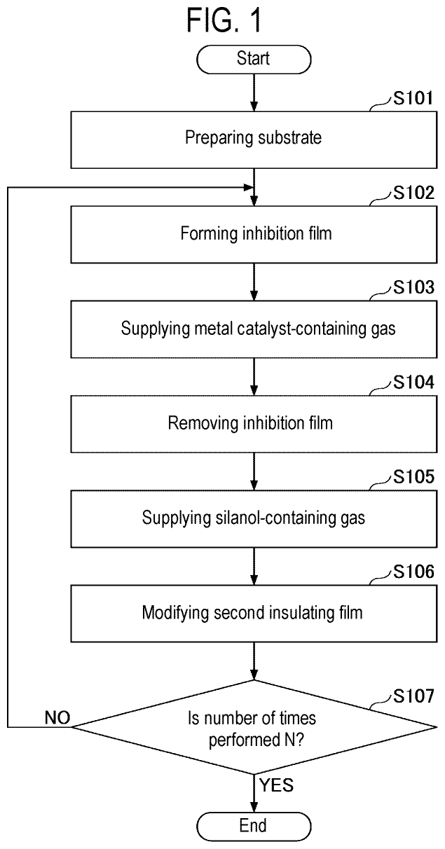

A film forming method according to an embodiment is described mainly with reference to FIGS. 1, 2A to 2E, 3A, and 3B. The film forming method includes, for example, steps S101 to S107 illustrated in FIG. 1. The film forming method may include at least steps S101 to S103 and S105 and may not include, for example, steps S104, S106, and S107. The film forming method may include steps other than steps S101 to S107 illustrated in FIG. 1.

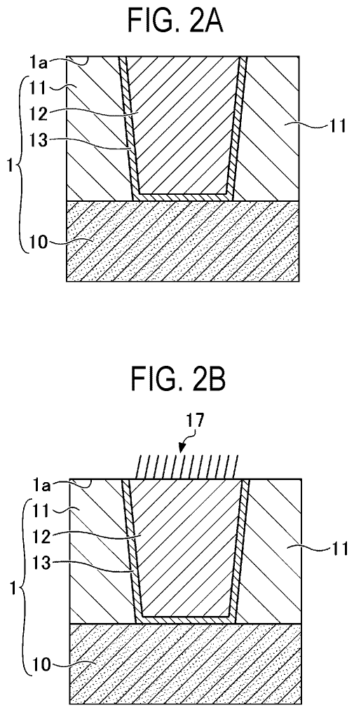

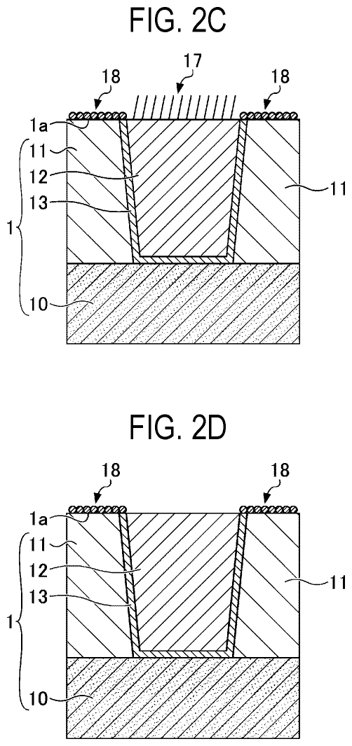

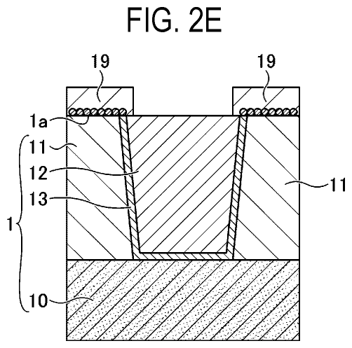

Step S101 includes preparing a substrate 1 as illustrated in FIG. 2A. The substrate 1 includes a base substrate 10. The base substrate 10 is, for example, a silicon wafer, a compound semiconductor wafer, or a glass substrate. The substrate 1 includes a surface of an insulating film (first insulating film) 11 and a surface of a conductive film (first conductive film) 12 in different regions of a substrate surface 1a. The substrate surface 1a is, for example, an upper surface of the substrate 1. The insulating film 11 and the conductive film 12 are formed over the base substrate 10. Another functional film may be formed between the base substrate 10 and the insulating film 11 or between the base substrate 10 and the conductive film 12.

The insulating film 11 is, for example, an interlayer insulating film. The interlayer insulating film is desirably a low dielectric constant (low-k) film. The insulating film 11 is, without being particularly limited to, for example, a SiO film, a SiN film, a SiOC film, a SiON film, or a SiOCN film. Herein, the SiO film means a film containing silicon (Si) and oxygen (O). An atomic ratio of Si to O in the SiO film is typically 1:2 but is not limited to 1:2. Similarly, each of the SiN film, the SiOC film, the SiON film, and the SiOCN film means a film containing corresponding elements and is not limited to a stoichiometric ratio. The insulating film 11 includes a recess in the substrate surface 1a. The recess is a trench, a contact hole, or a via hole.

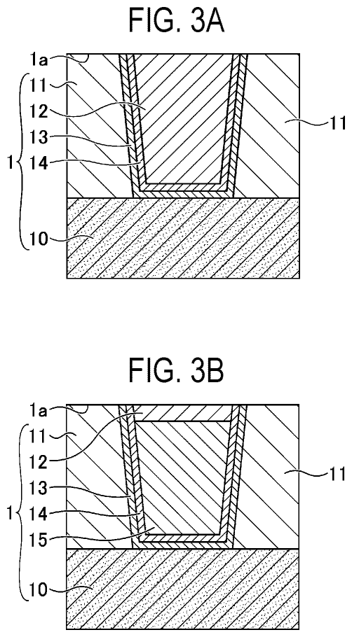

The conductive film 12 fills, for example, the recess of the insulating film 11. The conductive film 12 is, for example, a metal film. The metal film is, for example, a Cu film, a Co film, a Ru film, a W film, or a Mo film. The conductive film 12 may be a cap film. In other words, as illustrated in FIG. 3B, a second conductive film 15 may be embedded in the recess of the insulating film 11, and the second conductive film 15 may be covered by the conductive film 12. The second conductive film 15 is made of a metal different from that of the conductive film 12. For example, the second conductive film 15 is a Cu film, and the conductive film 12 (cap film) is a Co film or a Ru film.

The substrate 1 may further include a surface of a barrier film 13 on the substrate surface 1a. The barrier film 13 is formed between the insulating film 11 and the conductive film 12 to suppress metal diffusion from the conductive film 12 to the insulating film 11. The barrier film 13 is, without being limited to, for example, a TaN layer or a TiN layer. Herein, the TiN film means a film containing titanium (Ti) and nitrogen (N). An atomic ratio of Ti to N in the TIN film is typically 1:1 but is not limited to 1:1. Similarly, the TaN film means a film including corresponding elements and is not limited to a stoichiometric ratio.

As illustrated in FIG. 3A, the substrate 1 may further include a surface of a liner film 14 on the substrate surface 1a. The liner film 14 is formed between the conductive film 12 and the barrier film 13. The liner film 14 is formed on the barrier film 13 to assist in formation of the conductive film 12. The conductive film 12 is formed on the liner film 14. For example, the conductive film 12 is a Cu film, and the liner film 14 is a Co film or a Ru film.

Step S102 includes selectively forming an inhibition film 17, which inhibits adsorption of a metal catalyst-containing gas described later, on the surface of the conductive film 12 relative to the surface of the insulating film 11 (see FIG. 2B). The inhibition film 17 is, for example, a self-assembled monolayer (SAM). The inhibition film 17 is formed by supplying an organic compound gas to the substrate surface 1a.

The organic compound gas is not particularly limited but includes, for example, a thiol-based compound. Specific examples of the thiol-based compound include CF₃(CF₂)₅CH₂CH₂SH (1H, 1H, 2H, 2H-perfluorooctanethiol: PFOT) and CH₃(CH₂)₅SH (hexanethiol: HT).

The thiol-based compound is more likely to be chemically adsorbed onto the surface of the conductive film 12 than onto the surface of the insulating film 11. Therefore, the inhibition film 17 is selectively formed on the surface of the conductive film 12 relative to the surface of the insulating film 11. The inhibition film 17 is scarcely formed on the surface of the insulating film 11.

The organic compound gas is not limited to the thiol-based compound. The organic compound gas includes at least one selected from the group of, for example, the thiol-based compound, a carboxylic acid-based compound, a phosphonic acid-based compound, a nitro-based compound, an olefin-based compound, and an organic silane-based compound.

The thiol-based compound is represented by a general formula “R—SH.” The carboxylic acid-based compound is represented by a general formula “R—COOH.” The phosphonic acid-based compound is represented by a general formula “R—P(═O)(OH)₂.” The nitro-based compound is represented by a general formula “R—NO₂.” The olefin-based compound is represented by a general formula “R—CH═CH₂.” The organic silane-based compound is, for example, a trichlorosilane-based, methoxysilane-based, or ethoxysilane-based compound. The trichlorosilane-based organic compound is represented by a general formula “R—SiCl₃.” The methoxysilane-based organic compound is represented by a general formula “R—Si(OCH₃)₃.” The ethoxy silane-based organic compound is represented by a general formula “R—Si(OCH₂CH₃)₃.” In these general formulas, R represents, for example, a hydrocarbon group, or a hydrocarbon group in which at least a portion of hydrogen is replaced with fluorine. Specifically, for example, R is “CF₃—(CF₂)_{X}—”, “CF₃—(CF₂)_{X}—CH₂—CH₂—”, or “CH₃—(CH₂)_{X}—.” X is an integer from 1 to 17.

A temperature of the substrate 1 in step S102 is desirably greater than or equal to 120 degrees C. and less than or equal to 200 degrees C., and more desirably, greater than or equal to 120 degrees C. and less than or equal to 180 degrees C. If the temperature of the substrate 1 is greater than or equal to 120 degrees C., it is possible for the inhibition film 17 to exhibit inhibition performance. If the temperature of the substrate 1 is less than or equal to 200 degrees, it is possible to suppress thermal decomposition of the inhibition film 17. Additionally, if the temperature of the substrate 1 is less than or equal to 180 degrees C., it is possible for the inhibition film 17 to exhibit better inhibition performance.

An example of processing conditions of step S102 is as follows:
Flow rate of source gas of SAM: 20 sccm to 100 sccm
Processing time: 30 seconds to 600 seconds
Processing temperature: 120 degrees C. to 200 degrees C.
Processing pressure: 133 Pa to 2,000 Pa

Step S103 includes selectively adsorbing a metal catalyst-containing gas 18 onto the surface of the insulating film 11 relative to the surface of the conductive film 12 by supplying the metal catalyst-containing gas 18 to the substrate surface 1a on which the inhibition film 17 has been formed (see FIG. 2C). The metal catalyst-containing gas 18 contains a metal catalyst. The metal catalyst promotes a reaction that forms a second insulating film 19 from a silanol-containing gas described later (see FIG. 2E).

The metal catalyst-containing gas is desirably an organic metallic compound gas. Specifically, the organic metallic compound gas may be an organic aluminum compound gas or an organic titanium compound gas. An example of the organic aluminum compound gas includes trimethylaluminum (TMA) gas, triethylaluminum (TEA) gas, dimethylaluminum chloride gas, or dimethylaluminum isopropoxide (DMAI). The organic titanium compound gas is, for example, tetrakis(dimethylamino)titanium (TDMAT) gas.

A temperature of the substrate 1 in step S103 is desirably greater than or equal to 120 degrees C. and less than or equal to 200 degrees C., and more desirably, greater than or equal to 150 degrees C. and less than or equal to 180 degrees C. If the temperature of the substrate 1 is greater than or equal to 120 degrees C., it is possible for the metal catalyst-containing gas 18 to be selectively adsorbed onto the surface of the insulating film 11. If the temperature of the substrate 1 is greater than or equal to 150 degrees C., adsorption of the metal catalyst-containing gas 18 is enhanced. Additionally, if the temperature of the substrate 1 is less than or equal to 200 degrees C., it is possible to suppress the thermal decomposition of the inhibition film 17, thereby suppressing the metal catalyst-containing gas 18 from being adsorbed onto the surface of the conductive film 12.

An example of processing conditions of step S103 is as follows:
Flow rate of TMA gas: 10 sccm to 200 sccm
Flow rate of Ar gas: 1,200 sccm to 6,000 sccm
Processing time: 1 second to 30 seconds
Processing temperature: 120 degrees C. to 200 degrees C.
Processing pressure: 133 Pa to 1,200 Pa

Step S104 is performed after step S103 and before step S105, and includes removing the inhibition film 17 from the substrate 1 by increasing the temperature of the substrate 1 (see FIG. 2D). By removing the inhibition film 17 before step S105, a second insulating film 19 of high film quality may be formed in step S105. In step S104, an inert gas such as Ar gas is used.

A temperature of the substrate 1 in step S104 may be higher than the temperature of the substrate 1 in step S103. The temperature of the substrate 1 in step S104 is desirably, without being particularly limited to, greater than 200 degrees C. and less than or equal to 400 degrees C. If the temperature of the substrate 1 is greater than 200 degrees C., it is possible to promote the thermal decomposition of the inhibition film 17. Additionally, if the temperature of the substrate 1 is less than or equal to 400 degrees C., it is possible to suppress aggregation of the conductive film 12, thereby suppressing partial defects (disconnections) of the conductive film 12.

An example of processing conditions of step S104 is as follows:
Flow rate of Ar gas: 1,200 sccm to 6,000 sccm
Processing time: 1 second to 180 seconds
Processing temperature: 250 degrees C. to 350 degrees C.
Processing pressure: 133 Pa to 1,200 Pa

Step S105 includes forming a second insulating film 19 containing silicon and oxygen from the silanol-containing gas by supplying the silanol-containing gas to the substrate surface 1a onto which the metal catalyst-containing gas 18 has been adsorbed (see FIG. 2E). The silanol-containing gas contains a silanol group (Si—OH).

A reaction that forms the second insulating film 19 from the silanol-containing gas (e.g., a dehydration condensation reaction of the silanol group) is promoted by the metal catalyst-containing gas 18. The metal catalyst-containing gas 18 has been selectively adsorbed onto the surface of the insulating film 11 relative to the surface of the conductive film 12. Consequently, it is possible to selectively form the second insulating film 19 on the surface of the insulating film 11.

The silanol-containing gas is not particularly limited but, as the silanol-containing gas, for example, tris(tert-pentoxy)silanol (TPSOL), triethylsilanol, methyl bis(tert-pentoxy)silanol, or tris(tert-butoxy)silanol (TBSOL) may be used.

A temperature of the substrate 1 in step S105 is desirably greater than or equal to 200 degrees C. and less than or equal to 350 degrees C. If the temperature of the substrate 1 is greater than or equal to 200 degrees C., the second insulating film 19 has a good film quality. Additionally, if the temperature of the substrate 1 is less than or equal to 350 degrees C., it is possible to suppress the aggregation of the conductive film 12, thereby suppressing partial defects (disconnections) of the conductive film 12. The temperature of the substrate 1 is more desirably less than or equal to 300 degrees C.

An example of processing conditions of step S105 is as follows:
Flow rate of TPSOL gas: 50 mg/min to 500 mg/min
Flow rate of Ar gas: 1,200 sccm to 7,500 sccm
Processing time: 3 seconds to 90 seconds
Processing temperature: 250 degrees C. to 350 degrees C.
Processing pressure: 133 Pa to 4,000 Pa

Step S106, performed after step S105, includes modifying the second insulating film 19 by using gas containing hydrogen in a plasma state in a state where the temperature of the substrate 1 has been lowered. By modifying the second insulating film 19, it is possible to improve insulating properties of the second insulating film 19. Additionally, by lowering the temperature of the substrate 1, it is possible to suppress degradation of the conductive film 12 caused by the hydrogen gas in a plasma state.

A temperature of the substrate 1 in step S106 may be lower than the temperature of the substrate 1 in step S105. The temperature of the substrate 1 in step S106 is desirably, without being particularly limited to, greater than or equal to 120 degrees C. and less than or equal to 200 degrees C., and more desirably, greater than or equal to 150 degrees C. and less than or equal to 200 degrees C. If the temperature of the substrate is greater than or equal to 120 degrees C., the modification of the second insulating film 19 proceeds. If the temperature of the substrate 1 is greater than or equal to 150 degrees C., the modification of the second insulating film 19 progresses more easily. If the temperature of the substrate 1 is less than or equal to 200 degrees C., it is possible to suppress the degradation of the conductive film 12 caused by the hydrogen gas in a plasma state.

An example of processing conditions of step S106 is as follows:
Flow rate of H₂ gas: 200 sccm to 2,000 sccm
Processing time: 10 seconds to 120 seconds
Processing temperature: 150 degrees C. to 200 degrees C.
Processing pressure: 133 Pa to 665 Pa

Step S107 includes checking whether steps S102 to S106 have been performed N times (where N is an integer of 1 or more). If the number of times performed is less than N (step S107, “No”), since a film thickness of the second insulating film 19 has not reached a target thickness, steps S102 to S106 are performed again. If N is an integer of 2 or more, it is possible to modify the second insulating film 19 during stepwise formation, thereby modifying the second insulating film 19 throughout the entire thickness direction. If the number of times performed has reached N times (step S107, “Yes”), since the film thickness of the second insulating film 19 has reached the target thickness, the current process is completed.

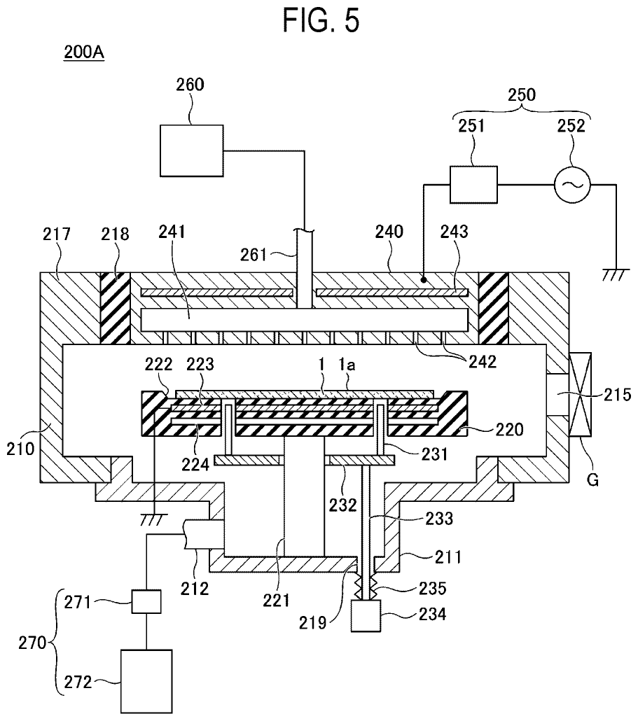

In the present embodiment, supplying the metal catalyst-containing gas 18 to the substrate surface 1a (step S103) and supplying the silanol-containing gas to the substrate surface 1a (step S105) are performed inside different processing containers 210 (see FIG. 5). An inner wall surface of each processing container 210 is exposed to only one of the metal catalyst-containing gas 18 and the silanol-containing gas.

By preventing exposure to both the metal catalyst-containing gas 18 and the silanol-containing gas, it is possible to suppress deposition of the second insulating film 19 on the inner wall surface of the processing container 210. Therefore, the cleaning frequency of the processing container 210 may be reduced. Alternatively, a cleaning time of the processing container 210, i.e., a time (a down time) during which the processing of the substrate 1 is stopped, may be shortened.

After the substrate 1 is loaded from an exterior of one processing container 210 into an interior thereof, the substrate 1 is placed on a stage 220 (see FIG. 5). In this state, step S103 is performed. Thereafter, the substrate 1 is unloaded from the interior of the one processing container 210 to the exterior thereof, loaded into the interior of another processing container 210 from the exterior thereof, and then placed on the stage 220. In this state, step S105 is performed.

Using different processing containers 210 in steps S103 and S105, it is possible to use different stages 220. This allows a temperature of each stage 220 to be set individually in steps S103 and S105, making it easy to change the temperature of the substrate 1. The temperature of the substrate 1 becomes equal to the temperature of the stage 220.

For instance, if the temperature of the substrate 1 is changed while the substrate 1 is placed on one stage 220, it takes time to change the temperature of the stage 220. In the present embodiment, different stages 220 with different temperatures are prepared, and the temperature of the substrate 1 is changed by transferring the substrate 1 from one stage 220 to another stage 220. Therefore, it is not necessary to change the temperature of the stage 220.

The temperature of the substrate 1 in step S105 is desirably higher than the temperature of the substrate 1 in step S103. By lowering the temperature of the substrate 1 during the adsorption of the metal catalyst-containing gas 18, it is possible to suppress the thermal decomposition of the inhibition film 17, thereby suppressing the metal catalyst-containing gas 18 from being adsorbed onto the surface of the conductive film 12. Further, by increasing the temperature of the substrate 1 during the formation of the second insulating film 19, it is possible to improve the film quality of the second insulating film 19. Additionally, since it is possible to shorten a time during which the substrate 1 remains at a high temperature, the aggregation of the conductive film 12 may be suppressed, thereby suppressing partial defects (disconnections) of the conductive film 12.

As previously explained, the temperature of the substrate 1 in step S103 is desirably greater than or equal to 120 degrees C. and less than or equal to 200 degrees C., and more desirably, greater than or equal to 150 degrees C. and less than or equal to 180 degrees C. If the temperature of the substrate 1 is greater than or equal to 120 degrees C., it is possible to selectively adsorb the metal catalyst-containing gas 18 onto the surface of the insulating film 11. Further, if the temperature of the substrate 1 is greater than or equal to 150 degrees C., the adsorption of the metal catalyst-containing gas 18 is enhanced. If the temperature of the substrate 1 is less than or equal to 200 degrees C., it is possible to suppress the thermal decomposition of the inhibition film 17, thereby suppressing the metal catalyst-containing gas 18 from being adsorbed onto the surface of the conductive film 12.

As previously explained, the temperature of the substrate 1 in step S105 is desirably greater than or equal to 200 degrees C. and less than or equal to 350 degrees C. If the temperature of the substrate 1 is greater than or equal to 200 degrees C., the second insulating film 19 exhibits a good film quality. If the temperature of the substrate 1 is less than or equal to 350 degrees C., it is possible to suppress the aggregation of the conductive film 12, thereby suppressing partial defects (disconnections) of the conductive film 12. The temperature of the substrate 1 is more desirably less than or equal to 300 degrees C.

However, as previously explained, the temperature of the substrate 1 in step S104 is higher than the temperature of the substrate 1 in step S103. Therefore, steps S103 and S104 are desirably performed inside different processing containers 210 and on different stages 220. By setting the temperature of each stage 220 individually, it is possible to easily change the temperature of the substrate 1.

If the temperature of the substrate 1 is the same in steps S104 and S105, it is desirable to perform steps S104 and S105 inside the same processing container 210 and on the same stage 220. This may reduce the number of the processing containers 210 required for processing a single substrate 1.

Additionally, as previously explained, the temperature of the substrate 1 in step S106 is lower than the temperature of the substrate 1 in step S105. Therefore, it is desirable to perform steps S105 and S106 inside different processing containers 210 and on different stages 220. By setting the temperature of each stage 220 individually, it is possible to easily change the temperature of the substrate 1.

If the temperature of the substrate 1 in step S106 is the same as the temperature of the substrate 1 in step S102, it is desirable to perform these steps S102 and S106 inside the same processing container 210 and on the same stage 220. This may reduce the number of the processing containers 210 required for processing a single substrate 1.

If steps S102 to S106 are repeatedly performed, that is, if N in step S107 is an integer of 2 or more, the K-th iteration of step S106 and the (K+1)-th iteration of step S102 may be performed inside the same processing container 210. Since the substrate 1 is not transferred, the processing time may be reduced.

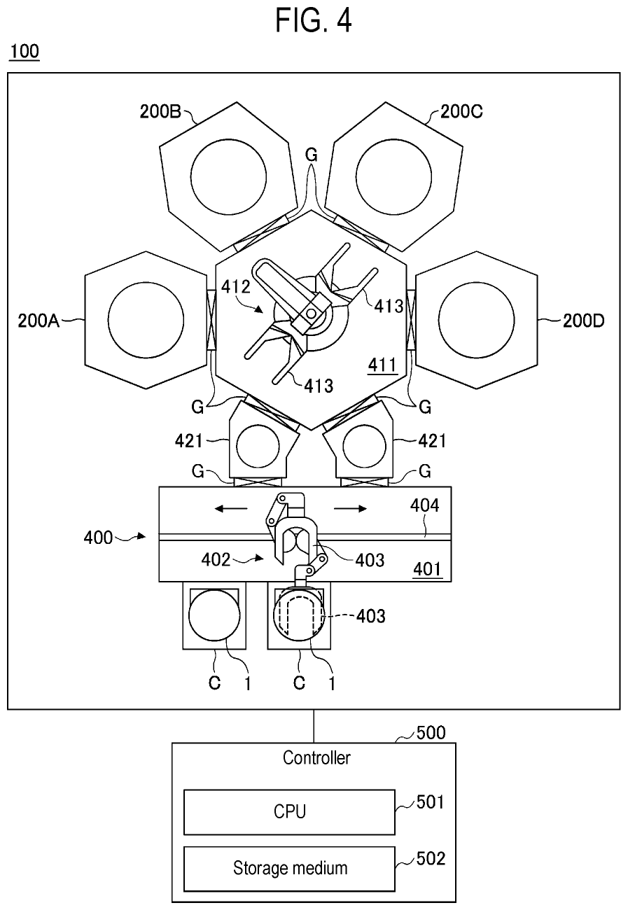

Next, a film forming apparatus 100 for performing the film forming method is described with reference to FIG. 4. As illustrated in FIG. 4, the film forming apparatus 100 includes a first processor 200A, a second processor 200B, a third processor 200C, a fourth processor 200D, a transfer part 400, and a controller 500. The first processor 200A performs step S102 in FIG. 1. The second processor 200B performs step S103 in FIG. 1. The third processor 200C performs steps S104 and S105 in FIG. 1. The fourth processor 200D performs step S106 in FIG. 1. The first processor 200A, the second processor 200B, the third processor 200C, and the fourth processor 200D may include the same structure or different structures.

Additionally, steps S103 and S105 may be performed in different processors. For example, the first processor 200A may perform the first iteration of steps S102, S103, and S106, while the second processor 200B may perform the first iteration of steps S104 and S105. The third processor 200C may perform the second iteration and subsequent iterations of steps S102, S103, and S106, while the fourth processor 200D may perform the second iteration and subsequent iterations of steps S104 and S105.

The transfer part 400 transfers the substrate 1 to the first processor 200A, the second processor 200B, the third processor 200C, and the fourth processor 200D. The controller 500 controls the first processor 200A, the second processor 200B, the third processor 200C, the fourth processor 200D, and the transfer part 400.

The transfer part 400 includes a first transfer chamber 401 and a first transferrer 402. An internal atmosphere of the first transfer chamber 401 is an ambient atmosphere. The first transferrer 402 is provided inside the first transfer chamber 401. The first transferrer 402 includes an arm 403 that holds the substrate 1 and travels along a rail 404. The rail 404 extends in an arrangement direction of carriers C.

The transfer part 400 includes a second transfer chamber 411 and a second transferrer 412. An internal atmosphere of the second transfer chamber 411 is a vacuum atmosphere. The second transferrer 412 is provided inside the second transfer chamber 411. The second transferrer 412 includes an arm 413 that holds the substrate 1. The arm 413 is disposed to be movable in a vertical direction and a horizontal direction and to be rotatable around a vertical axis. The first processor 200A, the second processor 200B, the third processor 200C, and the fourth processor 200D are connected to the second transfer chamber 411 via different gate valves G.

Further, the transfer part 400 includes load lock chambers 421 between the first transfer chamber 401 and the second transfer chamber 411. An internal atmosphere of the load lock chambers 421 is switched between a vacuum atmosphere and an ambient atmosphere by a pressure regulator which is not illustrated. As a result, the inside of the second transfer chamber 411 may always be maintained in the vacuum atmosphere. In addition, it is possible to suppress gas from flowing into the second transfer chamber 411 from the first transfer chamber 401. Gate valves G are provided between the first transfer chamber 401 and the load lock chambers 421 and between the second transfer chamber 411 and the load lock chambers 421.

The controller 500 is, for example, a computer and includes a central processing unit (CPU) 501 and a storage medium 502 such as a memory. The storage medium 502 stores programs that control various processes executed by the film forming apparatus 100. The controller 500 controls the operation of the film forming apparatus 100 by causing the CPU 501 to execute the programs stored in the storage medium 502. The controller 500 controls the first processor 200A, the second processor 200B, the third processor 200C, the fourth processor 200D, and the transfer part 400 so as to perform the film forming method.

Next, the operation of the film forming apparatus 100 is described. First, the first transferrer 402 takes the substrate 1 out of the carrier C, transfers the taken-out substrate 1 to the load lock chamber 421, and then exits from the load lock chamber 421. The internal atmosphere of the load lock chamber 421 is then switched from the ambient atmosphere to the vacuum atmosphere. Thereafter, the second transferrer 412 takes the substrate 1 out of the load lock chamber 421 and transfers the taken-out substrate 1 to the first processor 200A.

Next, the first processor 200A performs step S102. Thereafter, the second transferrer 412 takes the substrate 1 out of the first processor 200A and transfers the taken-out substrate 1 to the second processor 200B. During this time, since it is possible to maintain a surrounding atmosphere of the substrate 1 to be at the vacuum atmosphere, unintended oxidation of the substrate 1 may be suppressed.

Then, the second processor 200B performs step S103. Thereafter, the second transferrer 412 takes the substrate 1 out of the second processor 200B and transfers the taken-out substrate 1 to the third processor 200C. During this time, since it is possible to maintain the surrounding atmosphere of the substrate 1 to be at the vacuum atmosphere, unintended oxidation of the substrate 1 may be suppressed.

Then, the third processor 200C performs steps S104 and S105. Thereafter, the second transferrer 412 takes the substrate 1 out of the third processor 200C and transfers the taken-out substrate 1 to the fourth processor 200D. During this time, since it is possible to maintain the surrounding atmosphere of the substrate 1 to be at the vacuum atmosphere, unintended oxidation of the substrate 1 may be suppressed.

Next, the fourth processor 200D performs step S106. Thereafter, the controller 500 checks whether steps S102 to S106 have been performed a set number of times (N times). If the number of times performed has not reached the set number, the second transferrer 412 takes the substrate 1 out of the fourth processor 200D and transfers the taken-out substrate 1 to the first processor 200A. Next, the controller 500 controls the first processor 200A, the second processor 200B, the third processor 200C, the fourth processor 200D, and the transfer part 400 so as to perform steps S102 to S106 again.

On the other hand, if the number of times performed has reached the set number, the second transferrer 412 takes the substrate 1 out of the fourth processor 200D, transfers the taken-out substrate 1 to the load lock chamber 421, and then exits from the load lock chamber 421. Then, the internal atmosphere of the load lock chamber 421 is switched from the vacuum atmosphere to the ambient atmosphere. Thereafter, the first transferrer 402 takes the substrate 1 out of the load lock chamber 421 and accommodates the taken-out substrate 1 in the carrier C. Then, processing of the substrate 1 is completed.

Next, the first processor 200A is described with reference to FIG. 5. Further, since the second processor 200B, the third processor 200C, and the fourth processor 200D include the same configuration as the first processor 200A, illustration and description thereof are omitted.

The first processor 200A includes a substantially cylindrical airtight processing container 210. An exhaust chamber 211 is provided at a center portion of a bottom wall of the processing container 210. The exhaust chamber 211 has, for example, a substantially cylindrical shape that protrudes downward. An exhaust pipe 212 is connected to the exhaust chamber 211, for example, on a side surface of the exhaust chamber 211.

An exhaust source 272 is connected to the exhaust pipe 212 via a pressure controller 271. The pressure controller 271 includes, for example, a pressure regulating valve such as a butterfly valve. The exhaust pipe 212 is configured to be capable of depressurizing the interior of the processing container 210 by the exhaust source 272. The pressure controller 271 and the exhaust source 272 constitute a gas discharger 270 that discharges gas from the interior of the processing container 210.

A transfer port 215 is provided on a side surface of the processing container 210. The transfer port 215 is opened and closed by a gate valve G. The substrate 1 is loaded and unloaded between the inside of the processing container 210 and the second transfer chamber 411 (see FIG. 4) through the transfer port 215.

A stage 220, which is a holder for holding the substrate 1, is provided inside the processing container 210. The stage 220 holds the substrate 1 horizontally with the substrate surface 1a facing upward. The stage 220 is formed in a substantially circular shape in a plan view and is supported by a support member 221. A recess 222 of a substantially circular shape is formed at a surface of the stage 220 to place the substrate 1 having a diameter of, for example, 300 mm. The recess 222 has an inner diameter slightly larger than the diameter of the substrate 1. A depth of the recess 222 is substantially the same as, for example, a thickness of the substrate 1. The stage 220 is made of, for example, a ceramic material such as aluminum nitride (AlN). The stage 220 may also be made of a metal material such as nickel (Ni). Instead of the recess 222, a guide ring that guides the substrate 1 may be provided at a peripheral portion of the surface of the stage 220.

In the stage 220, for example, a grounded lower electrode 223 is embedded. A heater 224 is embedded below the lower electrode 223. The heater 224 heats the substrate 1 placed on the stage 220 to a set temperature by being fed with power from a power supply (not illustrated) based on a control signal from the controller 500 (see FIG. 4). When the entire stage 220 is made of a metal, the entire stage 220 functions as a lower electrode, and thus the lower electrode 223 does not need to be embedded in the stage 220. The stage 220 is provided with a plurality (e.g., three) of lifting pins 231 for holding and raising/lowering the substrate 1 placed on the stage 220. A material of the lifting pins 231 may be, for example, ceramic such as alumina (Al₂O₃), or quartz. Lower ends of the lifting pins 231 are attached to a support plate 232. The support plate 232 is connected to a lift 234 provided outside the processing container 210 via a lifting shaft 233.

The lift 234 is installed, for example, below the exhaust chamber 211. A bellows 235 is provided between an opening 219 for the lifting shaft 233, which is formed at a lower surface of the exhaust chamber 211, and the lift 234. The support plate 232 may be shaped to be raised and lowered without interfering with the support member 221 of the stage 220. The lifting pins 231 are configured to be movable up and down between above the surface of the stage 220 and below the surface of the stage 220 by the lift 234.

A gas supply part 240 is provided at a ceiling wall 217 of the processing container 210 via an insulating member 218. The gas supply part 240 constitutes an upper electrode and faces the lower electrode 223. A radio-frequency power supply 252 is connected to the gas supply part 240 via a matcher 251. By supplying a radio-frequency power of 450 kHz to 100 MHz from the radio-frequency power supply 252 to the upper electrode (gas supply part 240), a radio-frequency electric field is generated between the upper electrode (gas supply part 240) and the lower electrode 223, thereby generating capacitively coupled plasma. A plasma generator 250 that generates plasma includes the matcher 251 and the radio-frequency power supply 252. The plasma generator 250 may generate other plasma, such as inductively coupled plasma, without being limited to the capacitively coupled plasma. In processes in which plasma is not generated (e.g., steps S102 to S105), the gas supply part 240 does not need to constitute the upper electrode, and thus the lower electrode 223 is also unnecessary.

The gas supply part 240 includes a hollow gas supply chamber 241. A plurality of holes 242 for distributively supplying a process gas into the processing container 210 are disposed, for example, uniformly, at a lower surface of the gas supply chamber 241. In the gas supply part 240, a heater 243 is embedded, for example, above the gas supply chamber 241. The heater 243 is heated to a set temperature by being fed with power from the power supply (not illustrated) based on a control signal from the controller 500.

A gas supplier 260 is connected to the gas supply chamber 241 via a gas supply path 261. The gas supplier 260 supplies gas, used in at least one selected from the group of steps S102 to S106 in FIG. 1, to the gas supply chamber 241 via the gas supply path 261. Although not illustrated, the gas supplier 260 includes an individual pipe, an on-off valve provided in the middle of the individual pipe, and a flow rate controller provided in the middle of the individual pipe, for each type of gas. When the individual pipe is opened by the on-off valve, gas is supplied from a supply source to the gas supply path 261. A supply amount of the gas is controlled by the flow rate controller. Meanwhile, when the individual pipe is closed by the on-off valve, the supply of the gas from the supply source to the gas supply path 261 is stopped.

While the embodiments of the film forming method and film forming apparatus according to the present disclosure have been described, the present disclosure is not limited to the above-described embodiments. Various changes, modifications, substitutions, additions, deletions, and combinations are possible within the scope of the claims. These naturally fall within the technical scope of the present disclosure.

According to the present disclosure in some embodiments, it is possible to suppress deposition of contaminants on an inner wall surface of a processing container.

While certain embodiments have been described, these embodiments have been presented by way of example only and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A film forming method, comprising:
preparing a substrate including a surface of a first insulating film and a surface of a conductive film in different regions of a substrate surface;
selectively forming an inhibition film, which inhibits adsorption of a metal catalyst-containing gas, on the surface of the conductive film relative to the surface of the first insulating film;
supplying the metal catalyst-containing gas to the substrate surface on which the inhibition film has been formed to selectively adsorb the metal catalyst-containing gas onto the surface of the first insulating film relative to the surface of the conductive film; and
supplying a silanol-containing gas to the substrate surface onto which the metal catalyst-containing gas has been adsorbed to form a second insulating film containing silicon and oxygen from the silanol-containing gas,
wherein the supplying the metal catalyst-containing gas to the substrate surface and the supplying the silanol-containing gas to the substrate surface are performed inside different processing containers.

2. The film forming method of claim 1, wherein a temperature of the substrate during the supplying the silanol-containing gas is higher than a temperature of the substrate during the supplying the metal catalyst-containing gas.

3. The film forming method of claim 2, wherein the temperature of the substrate during the supplying the metal catalyst-containing gas is greater than or equal to 120 degrees C. and less than or equal to 200 degrees C.

4. The film forming method of claim 1, wherein a temperature of the substrate during the supplying the silanol-containing gas is greater than or equal to 200 degrees C. and less than or equal to 350 degrees C.

5. The film forming method of claim 1, comprising:
removing the inhibition film from the substrate by increasing a temperature of the substrate, after the supplying the metal catalyst-containing gas to the substrate surface and before the supplying the silanol-containing gas to the substrate surface.

6. The film forming method of claim 1, comprising:
modifying the second insulating film by using hydrogen gas in a plasma state, in a state where a temperature of the substrate has been lowered, after the supplying the silanol-containing gas to the substrate surface.

7. The film forming method of claim 1, wherein the supplying the metal catalyst-containing gas to the substrate surface and the supplying the silanol-containing gas to the substrate surface are repeatedly performed.

8. The film forming method of claim 1, wherein a temperature of the substrate during the supplying the metal catalyst-containing gas is greater than or equal to 120 degrees C. and less than or equal to 200 degrees C.

9. A film forming apparatus, comprising:
a processing container;
a holder configured to hold a substrate inside the processing container;
a gas supplier configured to supply gas to an interior of the processing container,
a gas discharger configured to discharge gas from the interior of the processing container,
a transferrer configured to load or unload the substrate into or from the processing container, and
a controller configured to control the gas supplier, the gas discharger, and the transferrer so as to perform the film forming method of claim 1.
